(19) United States
(12) Patent Application Publication
(10) Pub. No.: US 2025/0106978 A1
(43) Pub. Date: Mar. 27, 2025

(54) PRINTED CIRCUIT BOARD MODULE AND ELECTRONIC DEVICE

(71) Applicant: LG INNOTEK CO., LTD., Seoul (KR)

(72) Inventor: Ho Sung KANG, Seoul (KR)

(73) Assignee: LG INNOTEK CO., LTD., Seoul (KR)

(21) Appl. No.: 18/819,754

(22) Filed: Aug. 29, 2024

(30) Foreign Application Priority Data
Sep. 25, 2023 (KR) 10-2023-0128638

(51) Int. Cl. H05K 1/02; H05K 1/18

(52) U.S. Cl. CPC H05K 1/0203; H05K 1/18; H05K 2201/10757

(57) ABSTRACT

The present invention relates to a printed circuit board module and an electronic device including the same. A printed circuit board module according to one aspect includes: a printed circuit board including a hole; a heat dissipation member disposed on the printed circuit board and comprising a first surface formed on an upper surface and a second surface disposed stepwise downwardly with respect to the first surface; and an electronic component disposed on the second surface, wherein a region corresponding to the formed region of the second surface on a lower surface of the heat dissipation member is disposed with a protrusion protruding downwardly from the other region and coupled to the hole. [Representative Drawing] FIG. 1

### TECHNICAL FIELD

The teachings in accordance with exemplary and non-limiting embodiments of this invention relate generally to a printed circuit board module and an electronic device including the same.

### BACKGROUND ART

An electronic device includes a housing, a printed circuit board disposed in the housing, and one or more electronic components disposed on the printed circuit board. Since electronic components generate heat as they operate, and heat can overload the electronic components and cause failure of the set function, the heat dissipation structure of the module including the printed circuit board is an essential consideration.

In recent years, electronic devices have been miniaturized in consideration of vehicle fuel efficiency, but the placement of electronic components, including printed circuit boards, in the housing is difficult due to the narrow space in the housing and the generation of electrical noise between multiple electronic components.

### RELATED TECHNICAL DOCUMENTS

### Patent Documents

(Patent Document 1) Korean Public Utility Model Official Gazette No. 20-1998-0061577 (published on 5 Nov. 1998)

### SUMMARY OF THE INVENTION

### Technical Subject

The present invention is to provide a printed circuit board module and an electronic device including the same, which can improve heat dissipation efficiency and can secure a large space for placing components in a housing through miniaturization.

### Technical Solution

In one general aspect of the present invention, there may be provided a printed circuit board module, comprising:
a printed circuit board including a hole;
a heat dissipation member (heat sink) disposed on the printed circuit board, including a first surface formed on an upper surface and a second surface disposed stepwise downwardly with respect to the first surface; and
an electronic component disposed on the second surface, wherein a region corresponding to a formed region of the second surface in the lower surface of the heat dissipation member is disposed with a protrusion more downwardly protruded than other regions to be coupled to the hole.

In another general aspect of the present invention, there may be provided an electronic device, comprising:
a housing;
a printed circuit board including a printed circuit board module disposed in the housing, and including a hole;
a heat dissipation member (heat sink) disposed on the printed circuit board, the heat dissipation member including a first surface formed on an upper surface and a second surface disposed in a downward step with respect to the first surface; and
an electronic component disposed on the second surface, the heat dissipation member having a protrusion protruding downwardly from a region corresponding to the formed region of the second surface and coupled to the hole.

### Advantageous Effects

According to the present exemplary embodiment, the printed circuit board forms a hole in which a protrusion of the heat dissipation member is disposed, and the surface on which the electronic component is disposed on the heat dissipation member is formed at a lower level than other areas, so that the area on which the electronic component is disposed can be reduced in the up and down directions, thereby securing a wider space in the housing and facilitating heat dissipation of the drive heat of the electronic component.

### BRIEF DESCRIPTION OF THE DRAWINGS

FIG. 1 is a perspective view of a printed circuit board module according to a first exemplary embodiment of the present invention.

FIG. 2 is a top view of a printed circuit board module according to a first exemplary embodiment of the present invention.

FIG. 3 is a top view of a bottom surface of a printed circuit board module according to a first exemplary embodiment of the present invention.

FIG. 4 is an exploded perspective view of a printed circuit board module according to a first exemplary embodiment of the present invention.

FIG. 5 is a cross-sectional view illustrating a coupling structure of a printed circuit board, an electronic component, a heat sink, and a bracket according to a first exemplary embodiment of the present invention.

FIG. 6 is a perspective view of a printed circuit board module according to a second exemplary embodiment of the present invention.

FIG. 7 is a top view of a printed circuit board module according to a second exemplary embodiment of the present invention.

FIG. 8 is an exploded perspective view of a printed circuit board module according to a second exemplary embodiment of the present invention.

### BEST MODE

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

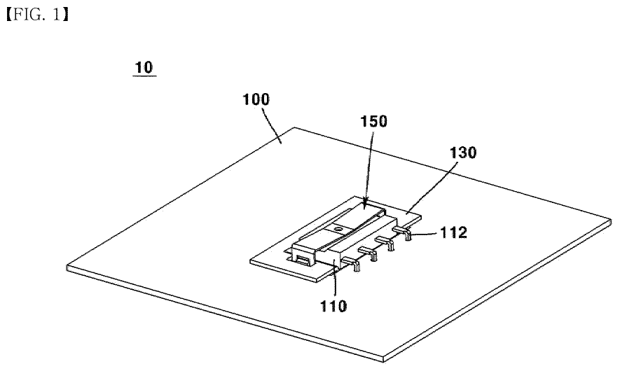

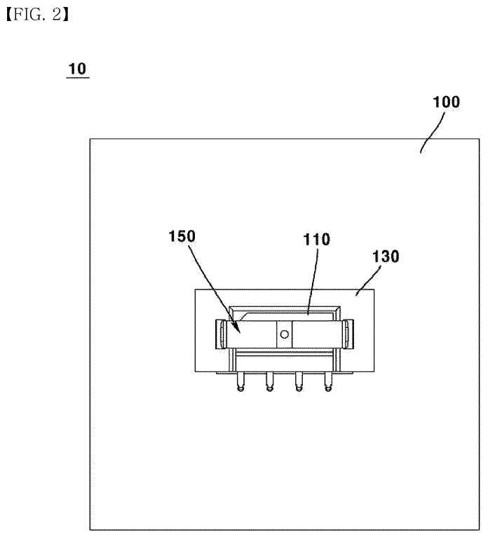

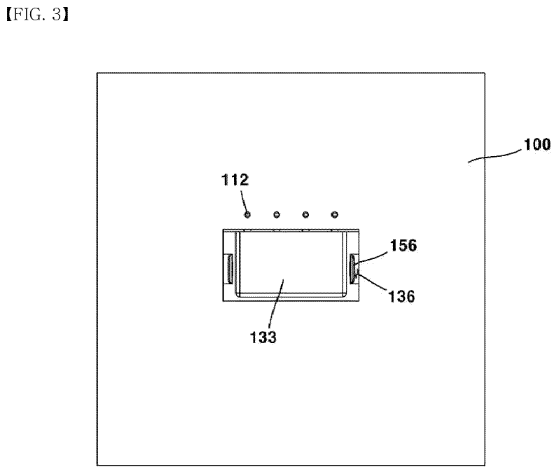

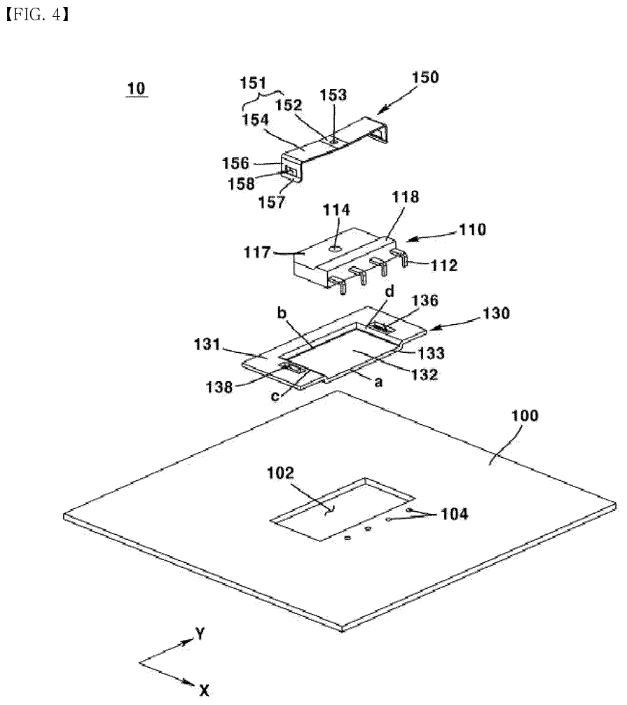

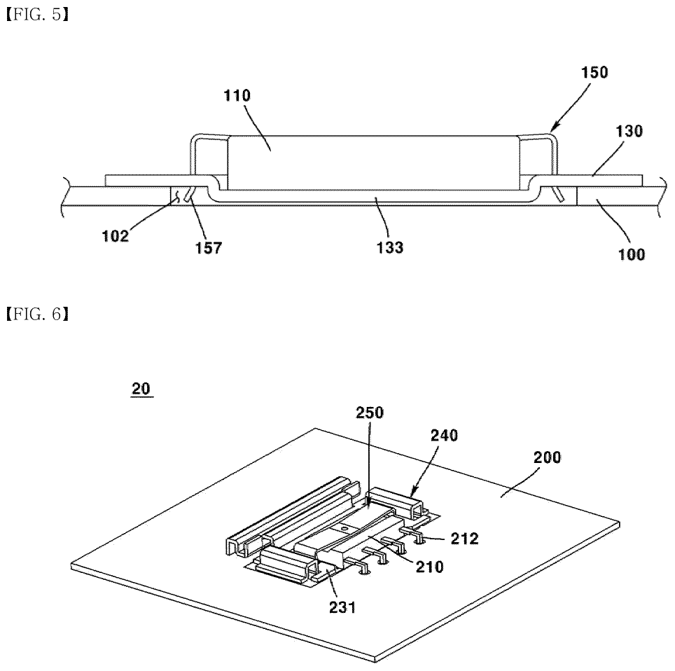

FIG. 1 is a perspective view of a printed circuit board module according to a first exemplary embodiment of the present invention, FIG. 2 is a top view of a printed circuit board module according to a first exemplary embodiment of the present invention, FIG. 3 is a top view of a bottom surface of a printed circuit board module according to a first exemplary embodiment of the present invention, FIG. 4 is an exploded perspective view of a printed circuit board module according to a first exemplary embodiment of the present invention, and FIG. 5 is a cross-sectional view illustrating a coupling structure of a printed circuit board, an electronic component, a heat sink, and a bracket according to a first exemplary embodiment of the present invention.

Referring now to FIGS. 1 to 5, a printed circuit board module (10) according to a first exemplary embodiment of the present invention may be disposed in a housing. The housing may form the exterior of an electronic device, and a space may be formed therein in which the printed circuit board module (10) is disposed.

The printed circuit board module (10) may include a printed circuit board (100), electronic components (110), a heat sink (130), and a bracket (150).

The printed circuit board (100) may be formed in the shape of a plate and disposed in a space within the housing. On the surface of the printed circuit board (100), one or more elements for driving the electronics may be disposed. The elements may be disposed on an upper surface or a bottom surface of the printed circuit board (100).

The printed circuit board (100) may include a hole (102). The hole (102) May be formed to penetrate through the other surface of the printed circuit board (100) from one surface. The hole (102) may have an oblong cross-sectional shape, but there is no limitation on the shape of the hole (102). The cross-sectional area of the hole (102) may be formed to be larger than the cross-sectional area of a protrusion (133) of a heat dissipation member (130), which will be described later. The hole (102) may include a first side, a second side opposite the first side, a third side connecting the first side to the second side, and a fourth side connecting the first side to the second side and opposite the third side. The first and second sides May be longer than the third and fourth sides. The first and second sides may be disposed to face each other in a first direction (X), and the third and fourth sides may be disposed to face each other in a second direction (Y) perpendicular to the first direction (X).

The printed circuit board 100 (may) include a pinhole (104). The pinhole (104) may be disposed on an outer side of the hole (102). The pinhole (104) may be disposed on an outer side of a first side of the hole (102). The pinhole (104) may be provided in plurality, spaced apart from each other along a longitudinal direction of the first side on the outer side of the first side. The pinholes (104) may be coupled with pins (112) of the electronic component (110), which will be described later.

The electronic component (110) may be disposed on the printed circuit board (100). The electronic component (110) may be for driving the electronics and may be electrically and physically connected to the printed circuit board (100). The electronic component (110) may include a core and pins 112 extending from the core.

The core may have a hexahedral shape. A plurality of step (staircase) faces (117, 118) of different heights in an upward and downward direction may be formed on an upper surface of the core. The plurality of step faces (117, 118) may include a first step face (117) and a second step face (118). The first step surface (117) and the second step surface (118) may be neighboring in the first direction (X). The first step surface (117) may be disposed lower than the second step surface (118). The second step surface (118) may be disposed above the first step surface (117). The second step surface (118) may be disposed neighboring the first side of the hole (102). The first step surface (117) may be disposed neighboring the second side of the hole (102).

A first through-hole (114) may be formed in the upper surface of the core. The first through-hole (114) may be shaped to penetrate downwardly from the upper surface of the core. The first through-hole (114) may be disposed on the first step surface (117).

The pin (112) may be shaped to protrude outwardly from a side of the core. The pin (112) may be disposed at least once on a side of the core neighboring the second step surface (118). The pin 112 may have at least one bent region. By the bent regions, the pin (112) may include a plurality of mutually perpendicular regions. In one example, the pin (112) may include a horizontal region projecting parallel to the printed circuit board (100) from a side of the core, and a vertical region bent downwardly and extending from an elongated end of the horizontal region. An end of the pin (112), i.e., a lower end of the vertical region, may be coupled to a pinhole (104) of the printed circuit board (100). The pin (112) may be soldered into the pinhole (104). The pin (112) may be provided in a plurality to correspond to the number of the pinholes (104), and may be spaced apart from each other along the sides of the core.

The heat dissipation member (130) may be disposed between the printed circuit board (100) and the electronic component (110). The heat dissipation member (130) may be formed of a metal material. The heat dissipation member (130) may be in surface contact with the electronic component (110) to dissipate heat generated by driving the electronic component (110) to the outside. The heat dissipation member (130) may be referred to as a heat sink.

The heat sink (130) may be formed in the shape of a plate. The surface of the heat sink (130), i.e., the upper and lower of the heat sink (130), may be formed with a plurality of step (staircase) faces having different heights in the upward and downward directions. The upper surface of the heat sink (130) may have a first surface (131) and a second surface (132) disposed in a downwardly stepped manner with respect to the first surface (131). The lower surface of the heat sink (130) May have a protrusion (133) that protrudes downwardly from the other areas. The lower surface of the protrusion (133) may be disposed at a step downwardly from the lower surface of the heat sink (130) than the other areas. The second surface 132 may be an upper surface of the protrusion (133).

The second side (132) or the protrusion (133) may comprise a first side (a, see FIG. 4) facing a first side of the hole (102), a second side (b) facing a second side of the hole (102), a third side (c) facing a third side of the hole (102), and a fourth side (d) facing a fourth side of the hole (102). The first side (a) and the second side (b) may be disposed opposite each other, and the third side (c) and the fourth side (d) may be disposed opposite each other. The first side (a) and the second side (b) may be disposed perpendicular to the third side (c) or the fourth side (d), respectively. The first side (a) and the second side (b) may be longer than the third side (c) and the fourth side (d), respectively.

The first side (a) of the second side (132) may be open in a first direction (X) parallel to the printed circuit board (100). The first side (a) of the second side (132) may form an edge of the heat dissipation member (130). Accordingly, a placement area for the pins (112) extending from the core may be secured.

Upon coupling the printed circuit board (100) with the heat sink (130), the protrusions (133) may be coupled within the hole (102). At least a portion of the protrusions (133) may be disposed on the inner side of the hole (102). At least a portion of the protrusions (133) may be disposed to overlap the printed circuit board (100) in a direction parallel to the printed circuit board (100). The electronic components (130) may be disposed so that at least a portion of them overlap in a horizontal direction with the printed circuit board (100). A lower surface of the electronic component (130) may be disposed lower than an upper surface of the printed circuit board (100).

Upon coupling the printed circuit board (100) with the heat sink (130), the lower surface of the protrusion (133) may form a plane co-planar with the lower surface of the printed circuit board (100). Alternatively, the lower surface of the protrusion (133) may be disposed in a step upwardly or downwardly from the lower surface of the printed circuit board (100). However, even in this case, the lower surface of the protrusion (133) may be disposed lower than the upper surface of the printed circuit board (100).

Except for the formed region of the protrusion (133), the lower surface of the heat sink (130) may be soldered to the upper surface of the printed circuit board (100). The upper surface of the printed circuit board (100) to which the lower surface of the heat dissipation member (130) is soldered may be a ground region.

The heat sink (130) may include a first coupling hole (136). The first coupling hole (136) may be shaped to penetrate downwardly from the upper surface of the heat sink (130). The first coupling hole (136) may be plural, and may be disposed opposite each other about the second surface (132) or the protrusion (133). The plurality of first coupling holes (136) may be disposed on the outer side of the second surface (132) or the protrusion (133).

The first coupling hole (136) may have an oblong cross-sectional shape. A projection (138) may be formed on the inner surface of the first coupling hole (136). The projection (138) may have a shape that protrudes from the inner surface of the first coupling hole (136) more than other areas. The projection (138) may be coupled to the second coupling hole (158) of a bracket (150), which will be described later. The upper surface of the projection (138) may have a sloped surface to facilitate engagement of the bracket (150).

The bracket (150) may be coupled to the printed circuit board (100), thereby securing the electronic component (110) and heat sink (130) to the printed circuit board (100).

The bracket (150) may be formed of a metal material.

The bracket (150) may comprise an upper surface portion (151) and a plurality of side portions (156) disposed at both ends of the upper surface portion (151). The upper surface portion (151) and the plurality of side portions (156) May be integrally formed.

The upper surface portion (151) may be disposed on the electronic component (110). The upper surface portion (151) may be arranged to cover the upper surface of the electronic component (110). At least some of the lower surfaces of the upper surface portion (151) may be in contact with the upper surface of the electronic component (110). The upper surface portion (151) may be coupled to the first step surface (117).

The upper surface portion (151) may include a first region (152) and a plurality of second regions (154) disposed on either side of the first region (152). The first region (152) may be disposed parallel to the first step surface (117), and may have a lower surface in contact with the first step surface (117). The first region (152) may include a second through-hole (153). The second through-hole (153) May be formed to penetrate the lower surface from the upper surface of the upper surface portion (151) and may be disposed in an upwardly facing direction with the first through-hole (114). The bracket (150) may be screw-coupled to the electronic component (110) by screws engaging the second through-hole (153) and the first through-hole (114).

The second region (154) may extend outwardly from both ends of the first region (152). The second region (154) may be inclined such that the distance to the upper surface of the electronic component (110) increases with distance from the first region (152). The second region (154) may be disposed at least partially spaced apart from the first step surface (117).

The plurality of side portions (156) may extend downwardly from both ends of the upper surface portion (151). The plurality of side portions (156) may be arranged to cover the sides of the electronic component (110). The plurality of side portions (156) may be spaced apart from the sides of the electronic component (110).

The plurality of side portions (156) may be coupled to the first coupling hole (136) of the heat dissipation member (heat sink, 130). The plurality of side portions (156) may include a second coupling hole (158). The second coupling hole (158) May be formed to penetrate from an inner surface to an outer surface of the side portions (156) and may be engaged with the projection (138). By engagement of the projection (138) and the second coupling hole (158), engagement of the bracket (150) with the heat sink (130) may be secured.

At the lower end of the plurality of lateral portions (156), a snagging (hitching) portion (157) may be formed. The snagging portion (157) may be sloped downwardly to increase the distance from the sides of the electronic component (110). The snagging portion (157) may contact a side of an inner surface of the first coupling hole (136) opposite a formed side of the projection (138).

Each of the plurality of side portions (156) may be elastically resilient in the direction of pressing on the lower surface of the projection (138) with the projection (138) engaged in the second coupling hole (158).

Furthermore, the side portions (156) may be inclined such that the horizontal distance to the side of the electronic component (110) increases towards the lower end.

According to the structure described above, it is possible to form a hole in which a protrusion of the heat dissipation member is disposed on the printed circuit board, and to form the surface on which the electronic component is disposed on the heat dissipation member in a shorter step than other areas, so that the area on which the electronic component is disposed can be reduced based on the up and down directions, thereby securing a wider space in the housing, and having the advantage of easily dissipating the drive heat of the electronic component.

On the other hand, although the present embodiment describes a structure for coupling with the heat sink (130) through the hole (102) in the printed circuit board (100) as an example, it is not limited thereto, and the printed circuit board (100) may be implemented with a groove formed more concave than other areas, such that the protrusion (133) of the heat sink (130) in the groove may be coupled. In this case, a lower surface of the protrusion (133) may be in contact with a bottom surface of the groove.

In the following, a printed circuit board module according to a second embodiment of the present invention will be described.

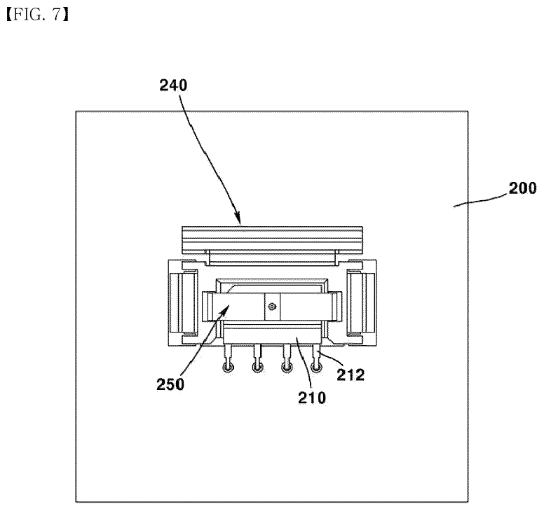

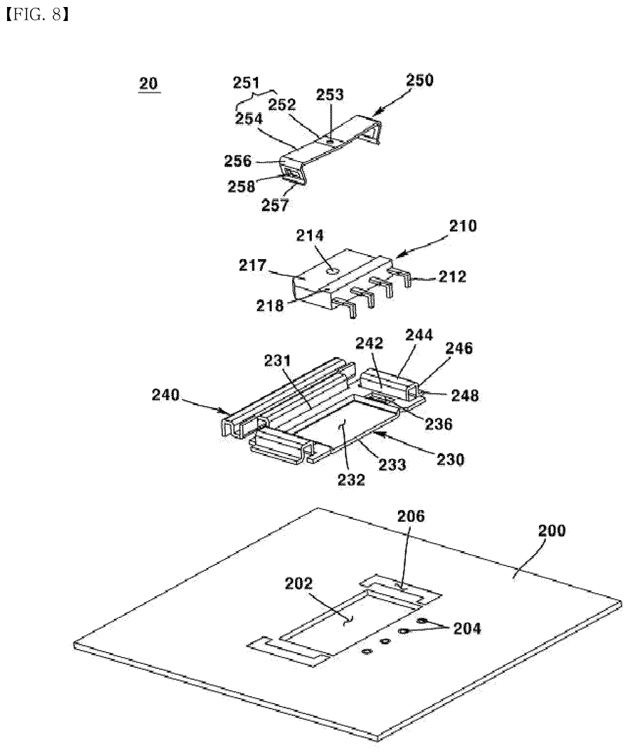

FIG. 6 is a perspective view of a printed circuit board module according to a second exemplary embodiment of the present invention, FIG. 7 is a top view of a printed circuit board module according to a second exemplary embodiment of the present invention, and FIG. 8 is an exploded perspective view of a printed circuit board module according to a second exemplary embodiment of the present invention.

The second embodiment is otherwise identical to the first embodiment, except that a reinforcement (240) in the heat dissipation member is added. Therefore, only the characteristic parts of the present embodiment will be described hereinafter, and the description of the first embodiment will be used for the remaining parts.

Referring to FIGS. 6 to 8, a heat dissipation member (230) according to the second embodiment may be disposed on a printed circuit board (200). A ground region (206) may be formed in the displacement region of the heat dissipation member (230) on the upper surface of the printed circuit board (200). The ground region (206) may be provided in a plurality, and may be disposed opposite each other relative to the hole (202) in the printed circuit board (200). The ground regions(206) may have an approximately ‘⊏’-shaped cross-sectional shape. At least some of the lower surface of the heat dissipation member (230) may be soldered to the ground region (206).

The heat dissipation member (heat sink, 230) may include a reinforcement (240). The reinforcement (240) may be disposed on the second, third and fourth sides of the heat sink (230), respectively, except for the first side of the heat sink (230) which faces the pinhole (204). The reinforcement (240) may include a plurality of plates perpendicular or parallel to each other. Referring to the reinforcement (240) disposed on the third or fourth side of the heat sink (230), the reinforcement (240) may include a first plate (242) protruding upwardly from the upper surface of the heat sink (230) above the other regions, a second plate (244) bent from an upper end of the first plate (242) and extending outwardly from the upper end of the first plate (242), a third plate (246) downwardly bent from an outside end of second plate (244) and extending outwardly, and a fourth plate (248) extending outwardly from a bottom of the third plate (246). The first plate (242) and the third plate (246) may be disposed parallel to each other. The second plate (244) and the fourth plate (248) may be disposed mutually parallel with each other. The first plate (242) and the third plate (246) may be disposed perpendicular to the second plate (244) or the fourth plate (248), respectively.

According to the structure as described above, it has the advantage that the heat dissipation efficiency can be improved by increasing the surface area within the heat dissipation member (230), and that the strength within the heat dissipation member (230) can be reinforced.

On the other hand, the reinforcement (240) may have different shapes at the second side, the third side, and the fourth side, in which case the reinforcement (240) disposed at the second side, which forms a relatively long elongate side, May include a greater number of plates than the reinforcement (240) disposed at the third side or at the fourth side.

Although all of the components comprising embodiments of the present invention have been described above as being combined or operating in combination, the invention is not necessarily limited to these embodiments, i.e., all of the components may optionally be combined in one or more combinations, as long as they are within the scope of the present invention. Furthermore, the terms ‘comprising,’ ‘consisting of,’ ‘consisting of,’ or ‘having’ as used herein, unless specifically indicated to the contrary, are intended to mean that the component in question may be inherent in, and therefore should be construed to be inclusive of, rather than exclusive of, other components. All terms, including technical or scientific terms, unless otherwise defined, shall have the same meaning as commonly understood by one having ordinary knowledge in the technical field to which the invention belongs. Commonly used terms, such as dictionary-defined terms, are to be interpreted as consistent with their contextual meaning in the relevant art and are not to be construed in an idealized or unduly formal sense unless expressly defined in the present invention.

The above description is merely an exemplary description of the technical ideas of the invention, and various modifications and variations will be apparent to one having ordinary knowledge in the technical field to which the invention belongs without departing from the essential features of the invention. Accordingly, the embodiments disclosed herein are intended to illustrate, not to limit, the technical ideas of the invention, and the scope of the technical ideas of the invention is not limited by these embodiments. The scope of protection of the present invention shall be construed in accordance with the following claims, and all technical ideas within the scope thereof shall be construed as falling within the scope of the present invention.

1-11. (canceled)

12. A printed circuit board module, comprising:
a printed circuit board including a hole;
a heat dissipation member disposed on the printed circuit board, including a first surface formed on an upper surface and a second surface disposed stepwise downwardly with respect to the first surface; and
an electronic component disposed on the second surface,
wherein a region corresponding to a formed region of the second surface in a lower surface of the heat dissipation member is disposed with a protrusion more downwardly protruded than other regions to be coupled to the hole.

13. The printed circuit board module of claim 12, wherein at least some of the lower surface of the heat dissipation member is soldered to the printed circuit board.

14. The printed circuit board module of claim 12, wherein the electronic component includes a core disposed on the second surface and a pin extending from the core, and
wherein the printed circuit board is disposed with a pinhole into which the pin is coupled.

15. The printed circuit board module of claim 14, wherein the second surface includes a first side, a second side opposite the first side, a third side connecting the first side and the second side, and a fourth side opposite the third side,
wherein the pin is at least partially disposed on the first side, and
wherein the first side forms an edge of the heat dissipation member.

16. The printed circuit board module of claim 12, wherein a lower surface of the protrusion forms a same plane as a lower surface of the printed circuit board.

17. The printed circuit board module of claim 12, wherein a lower surface of the electronic component is disposed lower than an upper surface of the printed circuit board

18. The printed circuit board module of claim 12, further comprising:
a bracket disposed on the electronic component and coupled to the printed circuit board,
wherein the bracket includes an upper surface portion disposed on an upper surface of the electronic component, and side portions bent from both ends of the upper surface portion and extending downwardly and disposed to cover sides of the electronic component.

19. The printed circuit board module of claim 18, wherein the heat dissipation member includes a first coupling hole and the side portion is coupled to the first coupling hole.

20. The printed circuit board module of claim 19, wherein a projection is formed at an inside of the first coupling hole, and the side portion includes a second coupling hole into which the projection is coupled.

21. The printed circuit board module of claim 12, wherein the heat dissipation member includes a reinforcement portion including at least two plates disposed at the edges and perpendicular to each other.

22. The printed circuit board module of claim 21, wherein the reinforcement portion is disposed on three sides of the electronic component, excluding an electrical connection area between the electronic component and the printed circuit board.

23. The printed circuit board module of claim 12, wherein among an upper surfaces of the printed circuit board, a surface in contact with the heat dissipation member is a ground area.

24. The printed circuit board module of claim 20, wherein the side portion has an elastic force in a direction in which an inner surface of the second coupling hole presses a lower surface of the projection.

25. The printed circuit board module of claim 18, wherein the upper surface portion includes a first region and a plurality of second regions disposed on both sides of the first region,
wherein the first region is in contact with a top surface of the electronic component, and
wherein the second region is spaced apart from the top surface of the electronic component.

26. An electronic device, comprising:
a housing;
a printed circuit board including a hole and disposed in the housing,
a heat dissipation member disposed on the printed circuit board, the heat dissipation member including a first surface formed on an upper surface and a second surface disposed in a downward step with respect to the first surface; and
an electronic component disposed on the second surface, the heat dissipation member having a protrusion protruding downwardly from a region corresponding to the formed region of the second surface and engaging the hole.

27. The electronic device of claim 26, wherein at least some of the lower surface of the heat dissipation member is soldered to the printed circuit board.

28. The electronic device of claim 26, wherein the electronic component includes a core disposed on the second surface and a pin extending from the core, and
wherein the printed circuit board is disposed with a pinhole into which the pin is coupled.

29. The electronic device of claim 28, wherein the second surface includes a first side, a second side opposite the first side, a third side connecting the first side and the second side, and a fourth side opposite the third side,
wherein the pin is at least partially disposed on the first side, and
wherein the first side forms an edge of the heat dissipation member.

30. The electronic device of claim 26, wherein a lower surface of the protrusion forms a same plane as a lower surface of the printed circuit board.
